(19) United States
(12) Patent Application Publication
(10) Pub. No.: US 2025/0323066 A1
(43) Pub. Date: Oct. 16, 2025

(54) RINSING STATION AND DEVICE FOR PRODUCING CONTACT METALLIZATIONS

(71) Applicant: Pac Tech – Packaging Technologies GmbH, Nauen (DE)

(72) Inventor: Thorsten Krause, Hoppegarten (DE)

(21) Appl. No.: 19/175,028

(22) Filed: Apr. 10, 2025

(30) Foreign Application Priority Data
Apr. 11, 2024 (DE) 20 2024 101 781.1

(51) Int. Cl. H01L 21/67

(52) U.S. Cl. CPC H01L 21/67051

(57) ABSTRACT

A rinsing station (10) includes a basin (12) forming a processing chamber (11) and serving to receive a rinsing liquid, in particular containing deionized water, for rinsing a wafer (14) receivable in the processing chamber, the basin having at least one inlet (15) for feeding the rinsing liquid into the basin. The inlet is designed as a nozzle arrangement (16), the nozzle arrangement having at least one nozzle (17) by means of which the rinsing liquid can be applied being directed onto the wafer, the nozzle being designed as a fan nozzle or a full-cone nozzle or a hollow-cone nozzle.

This application claims the benefit of German Utility Model Application No. 20 2024 101 781.1 Filed on Apr. 11, 2024, the disclosure of which is incorporated herein by reference.

### TECHNICAL FIELD

The invention relates to a rinsing station, comprising a basin forming a processing chamber for receiving a rinsing liquid, in particular containing deionized water, for rinsing a wafer receivable in the processing chamber, the basin having at least one inlet for feeding the rinsing liquid into the basin. The invention also relates to a device for producing contact metallizations on terminal faces of wafers, the device comprising at least one such rinsing station.

### BACKGROUND

Producing contact metallizations on the terminal faces of chips, said contact metallizations being also referred to as under bump metallizations (UBM) in specialized terminology, is generally carried out on the wafer plane, i.e., the entire wafer having the plurality of chips formed thereon undergoes a chemical process before the chips are singulated from the wafer, a process in which the intermediate metallization (referred to as under bump metallization) is applied on the terminal faces of the chips, which have a surface metallization made of aluminum or copper in their initial state, said intermediate metallization serving as an adhesive primer for subsequently applied solder bumps made of a solder material. Only after the solder bumps have been applied, the chips are eventually singulated from the wafer.

An apparatus for producing such contact metallizations on terminal faces of wafers, which, for example, is known from CN 203760439 U and DE 20 2022 105 493 U1, regularly comprises at least one cleaning station, in which the wafers are cleaned by means of a cleaning liquid, such as nitric acid; at least one depositing station, in which a contact metal is deposited on the terminal faces from a metal solution, which usually comprises a metal, in particular nickel, zinc, palladium, gold or the like, dissolved in a liquid, such as nitric acid, depositing taking place either galvanically or electrolessly depending on the design of the device; at least one rinsing station, in which wafer surfaces are rinsed or cleaned using a rinsing liquid, in particular containing deionized water, in particular to remove residue from the depositing station or the cleaning station; and at least one drying station in which the wafer surfaces are dried.

Such a rinsing station typically comprises a basin forming a processing chamber and serving to receive the rinsing liquid for rinsing a wafer which can be received in the processing chamber. The rinsing liquid is fed into the processing chamber via an inlet of the basin, which in practice is formed by an opening or a simple hole.

A disadvantage of a rinsing station of this kind is in particular that the rinsing liquid fed into the basin via an inlet of this kind, with the wafer received in the processing chamber, does not allow optimal rinsing and/or cleaning of the wafer, during which residue on the wafer surface would essentially be completely removed. The aforementioned disadvantage means that a quality of the contact metallizations produced by the device for producing contact metallizations, said device comprising a rinsing station of this kind, is reduced.

### SUMMARY

The object of the present invention is therefore to propose a rinsing station and a device for producing contact metallizations which allow an improved rinsing and/or cleaning of a wafer and/or producing contact metallizations of a higher quality.

This object is attained by a rinsing station and a device for producing contact metallizations.

The rinsing station according to the invention comprises a basin forming a processing chamber and serving to receive a rinsing liquid, in particular containing deionized water, for rinsing a wafer receivable in the processing chamber, the basin having at least one inlet for feeding the rinsing liquid into the basin, the inlet being designed as a nozzle arrangement, the nozzle arrangement having at least one nozzle by means of which the rinsing liquid can be applied being directed onto the wafer, the nozzle being designed as a fan nozzle or a full-cone nozzle or a hollow-cone nozzle.

According to the invention, the rinsing station comprises a basin forming a processing chamber and serving to receive a rinsing liquid, in particular containing deionized water, for rinsing a wafer receivable in the processing chamber. In principle, the rinsing station can be used for rinsing any object suitable for undergoing a rinsing process, a material of the object being able to comprise metallic materials and/or plastics and/or ceramic materials. However, the rinsing station is particularly suitable for rinsing a wafer, a wafer surface of the wafer being able to be rinsed and/or cleaned during the rinsing process. The rinsing liquid may contain deionized water. In addition to deionized water, the rinsing liquid may contain additives, in particular solvents, for example isopropyl alcohol (IPA). The rinsing liquid can be deionized water.

Deionized water is also referred to as demineralized water. Depending on the purity of the deionized water, a distinction can be made between purified water and/or low-salt water, ultrapure water or pure water and high-purity water. The remaining electrical conductivity of the deionized water decreases from purified water or low-salt water via ultrapure water or pure water to high purity water. Preferably, the deionized water can be ultrapure water in order to achieve an optimized rinsing result. The basin can have an opening through which the wafer can be inserted in the processing chamber, preferably from above, to carry out a rinsing process and can be removed from the processing chamber following the rinsing process. Furthermore, the basin can have a quadrilateral, preferably rectangular, base area or cross-sectional area. Furthermore, the basin can have a bottom wall and four lateral walls. The bottom wall and the lateral walls can delimit the processing chamber, which can extend from the bottom wall to the opening. The four lateral walls can comprise two longitudinal walls and two transverse walls. Preferably, the longitudinal walls are longer than the transverse walls. The longitudinal walls may also have a length corresponding to the transverse walls.

According to the invention, the basin has at least one inlet for feeding the rinsing liquid into the basin, the inlet being designed as a nozzle arrangement, the nozzle arrangement having at least one nozzle, by means of which the rinsing liquid can be applied being directed onto the wafer, the nozzle being designed as a fan nozzle, which is also referred to as a flat-jet nozzle, or full-cone nozzle or hollow cone nozzle.

Accordingly, the basin has at least one inlet, preferably disposed to the side of the basin and designed as a nozzle arrangement, the nozzle arrangement having at least one nozzle designed as a fan nozzle or a full-cone nozzle or hollow-cone nozzle, by means of which the rinsing liquid can be applied and/or sprayed being directed onto the wafer, with the wafer received in the basin, the design of the nozzle as a fan nozzle or a full-cone nozzle or a hollow-cone nozzle making it possible to advantageously fan out and/or enlarge a jet of the rinsing liquid formed by the nozzle. Such a fanned-out and/or enlarged jet leads to optimized rinsing and/or cleaning of the wafer. Preferably, the nozzle arrangement has at least two, particularly preferably at least three, nozzles. The nozzle arrangement can therefore have a plurality of nozzles. Fan nozzles, full-cone nozzles and/or hollow-cone nozzles can be combined with each other. Preferably, the nozzles can be disposed on at least one lateral wall of the basin, preferably on two opposing lateral walls of the basin. Preferably, the nozzles can be disposed on the respective lateral wall in an area of an edge of the lateral wall, preferably in a row, the nozzles being able to be disposed in a respective row preferably at equal distances from one another. It is also conceivable that the nozzles are disposed on all four lateral walls of the basin so that the wafer can be rinsed from all sides. Furthermore, the nozzles can be designed in such a manner that a jet angle, i.e., an angle at which a respective jet can be emitted from the respective nozzle, can be adjusted. If the rinsing station is a component of a device for producing contact metallizations, the rinsing station enables the production of contact metallizations with a higher quality, in particular since residue from a depositing process preceding the rinsing process and carried out by means of a depositing station of the device and/or from a cleaning process preceding the rinsing process and carried out by means of a cleaning station of the device can be removed essentially completely.

Advantageously, the basin can have an outlet, preferably disposed on the bottom of the basin, preferably designed as a free drain, and serving to drain the rinsing liquid from the basin. During a rinsing process, residue from a wafer surface of the wafer can pass into the rinsing liquid and can thus contaminate the rinsing liquid. The residue can, for example, result from a depositing station of a device for producing contact metallizations, said device also including the rinsing station, or from a cleaning station of the device. The rinsing liquid contaminated during the rinsing of the wafer can be drained from the basin via the outlet. The basin can also be drained, i.e., emptied, completely via the drain. The draining or emptying can be comparatively slow or comparatively fast. If the outlet is designed as a free drain, the rinsing liquid can be drained and/or emptied from the basin comparatively quickly without backwater.

In addition to a cleaning effect, which can result from an application of the rinsing liquid to the wafer by means of the nozzles and possibly from an immersion of the wafer in the basin filled with the rinsing liquid when the wafer is inserted into the basin, a further cleaning effect can advantageously result from the fact that the basin filled with the rinsing liquid can be emptied comparatively quickly via the free drain by utilizing an adhesive force of the rinsing liquid on the wafer surface when the wafer is disposed in the basin. The rinsing process can comprise several rinsing cycles, the basin being able to be emptied by draining the contaminated rinsing liquid via the outlet from the basin when the wafer is disposed in the basin and subsequently being able to be refilled by feeding fresh rinsing liquid into the basin in particular via the inlet. The fresh rinsing liquid can be fed into the basin via the inlet while the contaminated rinsing liquid is being drained from the basin. At the same time, the entire basin can be emptied, as more contaminated rinsing liquid can be drained from the basin via the outlet than fresh rinsing liquid can be fed into the basin via the inlet per time unit with regard to volume. The inlet can be connected to a vessel which can be part of the rinsing station and in which the fresh rinsing liquid can be stored. The outlet can also be connected to a vessel which can be part of the rinsing station and from which the contaminated rinsing liquid can be drained and/or in which it can be stored. The outlet can also be connected to a public sewage network. Once the wafer has been cleaned and/or the residue has been removed from it after carrying out a certain number rinsing cycles, the wafer can be removed from the basin. After the rinsing process, the basin can be emptied before or even after the wafer has been removed from the basin and can subsequently be refilled when the wafer has been removed from the basin, so that the rinsing station is available for carrying out a rinsing process on another wafer.

In the rinsing process, a process step can be intended during which as much contaminated rinsing liquid is drained from the basin via the outlet as fresh rinsing liquid is fed into the basin via the inlet per time unit with regard to volume, whereby continuous and homogeneous rinsing of the wafer can take place.

Advantageously, the rinsing station can comprise a sample-analysis device, which can be configured to analyze a sample of the rinsing liquid taken from the basin. By means of the sample-analysis device, a degree of purity of the rinsing liquid can be determined and/or measured, on the basis of which it can be assessed whether the wafer has been cleaned and/or freed from the residue, as a result of which the rinsing process can be terminated.

Advantageously, the basin can have an overflow, the sample-analysis device being able to be connected to the overflow in such a manner that the sample can be taken from the rinsing liquid drained from the basin via the overflow. For this purpose, a deflection channel of the basin can be provided on the exterior of the basin, the rinsing liquid drained from the basin via the overflow being able to be fed to the sample analysis device via the deflection channel. The deflection channel can have an exit which leads to an overflow vessel of the sample-analysis device from where the rinsing liquid can reach a sample sensor of the sample-analysis device for a measuring probe of the sample-analysis device via a measuring path of the sample-analysis device which serves for calming and preventing a dry run. The measuring path can be made in one piece with the overflow vessel. After the basin has been emptied by discharging the rinsing liquid via the outlet, the rinsing liquid can be fed into the basin via the inlet at least until a filling level of the rinsing liquid in the basin reaches the overflow, which can be disposed on at least one lateral wall of the basin. The sample can be easily taken from the basin via the overflow, without requiring an additional removal device, such as a pump or the like. It would also be conceivable to connect the sample analysis device to the outlet so that the sample can be taken via the outlet while the rinsing liquid is being drained from the basin. Preferably, the nozzles are disposed below the overflow.

Advantageously, the lateral walls of the basin can each have a perforation which can preferably be formed in the area of the edge of the lateral walls and can form the overflow. The perforation can be designed in the form of a hole arrangement, which can have a plurality of holes, preferably disposed in a row. Preferably, the perforation and/or hole arrangement can have a row of holes extending parallel to the edge of the respective lateral wall, said edge being disposed in the area of the opening of the basin. The holes can preferably be designed identically.

In principle, a geometry and/or a size of the cross section of the holes can be suitably selected. For example, the holes can have a cross section having a circular or square geometry. The design of the overflow as the perforation provided in the lateral walls makes it possible to take a sample representative of the degree of purity of the rinsing liquid in the entire basin, i.e., not just locally in the basin.

Advantageously, the basin can be configured such that a transport receptacle having a plurality of wafers received therein can be inserted into the basin from above. It is thus possible to subject a plurality of wafers to the rinsing process simultaneously. The transport receptacle can be formed as a basket. In the transport receptacle, the wafers can be disposed parallel to each other, at equal distances, positioned in vertical or horizontal alignment. On the bottom wall of the basin, supporting elements of the basin can be disposed and/or fixed which can support the transport receptacle having the wafers received therein.

Advantageously, the basin can have another inlet for feeding the rinsing liquid into the basin. The other inlet can be designed as at least one opening and/or at least one hole. Preferably, the other inlet can be disposed to the side of the basin. In this context, the other inlet can be disposed on at least one lateral wall of the basin, preferably on two opposite lateral walls, preferably adjacent to an edge of the respective lateral wall located in the area of the bottom wall. The provision of the additional inlet enables the basin to be filled or flooded comparatively quickly. The rinsing liquid can be fed into the basin via the inlet and the other inlet simultaneously.

Advantageously, the rinsing station can comprise at least one pipe arrangement connected to the inlet. Furthermore, the rinsing station can comprise another pipe arrangement connected to the other inlet. The pipe arrangement can comprise a first distribution piping connected to the nozzles and a second distribution piping formed separately from the first distribution piping and connected to the other nozzles. The other pipe arrangement can be designed as a third distribution piping. The first and second distribution piping and/or the third distribution piping can each have a connection for connecting the respective distribution piping to an inlet pipe for supplying rinsing liquid or to an outlet pipe for draining rinsing liquid. The inlet pipe can be connected to the vessel for the fresh rinsing liquid and the outlet pipe can be connected to the vessel for the contaminated liquid and/or to the public sewage network.

Advantageously, the rinsing station can comprise a control device, which can be configured to at least control feeding the rinsing liquid into the basin via the inlet. Furthermore, the control device can be configured to control feeding the rinsing liquid into the basin via the other inlet and/or to control draining the rinsing liquid from the basin via the outlet. The basin can comprise valves which are assigned to the inlet and/or the other inlet and/or the outlet and which can be controlled by means of the control device. A shared valve can be assigned to the nozzles and another shared valve can be assigned to the other nozzles. A separate valve can also be assigned to each nozzle and/or each other nozzle. The control device can interact with the sample analysis device in such a manner that an analysis result yielded by means of the sample analysis device, in particular the degree of purity of the rinsing liquid, can be transmitted to the control device so that the control device can control the valves depending on the analysis result. In particular, the control device can control rinsing times and/or rinsing quantities Advantageously, the rinsing station can comprise a filling-level measuring device, which can be configured to measure a filling level in the basin. The control device can interact with the filling-level measuring device in such a manner that a filling level measured by means of the filling-level measuring device can be transmitted to the control device so that the control device can control the valves depending on the filling level.

Advantageously, the basin can have a, preferably pivotable, lid, which can cover an opening of the basin in a closed position of the lid. The lid can reduce a heat exchange between the rinsing liquid in the basin and an environment. In addition, the rinsing liquid in the basin can be protected from contamination from the outside in this manner. Spray mist can also be avoided in this manner. To insert the wafer in the processing chamber and/or to remove the wafer from the processing chamber, the lid can then be opened and subsequently closed again. The lid can also be designed to be movable or otherwise openable or closable.

Advantageously, the nozzle arrangement can have at least one other nozzle by means of which the rinsing liquid can be applied being directed onto the lid, the other nozzle preferably being able to be designed as a fan nozzle or a full-cone nozzle or a hollow-cone nozzle. Preferably, the nozzle arrangement has at least two other nozzles. The nozzle arrangement can therefore have a plurality of other nozzles. In this context, fan nozzles, full-cone nozzles and/or hollow-cone nozzles can be combined with each other. Preferably, the other nozzles can be disposed on at least one lateral wall of the basin, preferably on two opposing lateral walls of the basin, on which preferably no nozzles are disposed. Preferably, the other nozzles can be disposed on the respective lateral wall in an area of an edge of the lateral wall, preferably in a row, the other nozzles being able to be disposed in a row, preferably at equal distances to each other. It is also conceivable that the other nozzles are disposed on all four lateral walls of the basin so that the lid can be rinsed on all sides. Furthermore, the other nozzles can be designed in such a manner that a jet angle, i.e., an angle at which a respective jet from the respective other nozzle can be emitted, can be adjusted. The lid can be rinsed or cleaned by means of the other nozzle, whereby contamination of the lid, which can lead to contamination of the wafer and/or can falsify the analysis result due to contamination of the rinsing liquid, can be prevented. If the other nozzle is designed as a fan nozzle or a full-cone nozzle or a hollow-cone nozzle, a fanned-out or enlarged jet formed by means of said nozzle leads to an optimized rinsing and/or cleaning of the lid. Preferably, the other nozzles can be disposed above the overflow. The rinsing liquid can be applied being directed onto the wafer also by means of the other nozzles. Depending on whether the wafer is disposed parallel or transverse to a length of the basin in the processing chamber, in particular depending on the dimensions of the wafer, for example depending on whether the wafer is an 8-inch wafer or a 12-inch wafer, the other nozzles can then be adjusted in such a manner that the jet is directed onto the wafer. The rinsing station can be provided in particular for rinsing an 8-inch wafer and/or a 12-inch wafer.

Advantageously, the rinsing station can comprise a temperature-control device for controlling the temperature of the rinsing liquid, preferably before the rinsing liquid is fed into the basin. The temperature-control device can comprise a heat-exchanger arrangement. The temperature-control device can be used to increase and/or decrease the temperature of the rinsing liquid. Cold rinsing liquid and warm rinsing liquid can also be mixed, a desired mixing temperature being able to be obtained by mixing the cold rinsing liquid with the warm rinsing liquid in an appropriate ratio. The rinsing station can further comprise a temperature measuring device which can measure the temperature of the rinsing liquid before the rinsing liquid is fed into the basin and/or can measure the temperature of the rinsing liquid in the basin. The control device can interact with the temperature measuring device in such a manner that a temperature measured by the temperature measuring device can be transmitted to the control device so that the control device can control the valves as a function of the temperature.

In a method for rinsing a wafer by means of a rinsing station, the wafer can be received in a processing chamber formed by a basin of the rinsing station. The wafer can be inserted in the processing chamber filled with a rinsing liquid, in particular containing deionized water, the wafer being able to be immersed in the rinsing liquid and/or be submerged in the rinsing liquid. As a result of the immersion and/or submersion in the rinsing liquid, the wafer can be cleaned. Subsequently, the basin can be emptied of the rinsing liquid by draining the rinsing liquid from the basin via an outlet, which is preferably disposed at the bottom of the basin and is preferably designed as a free drain. Subsequently, the basin can be filled with the rinsing liquid by feeding rinsing liquid into the basin via at least one inlet of the basin. In this context, the rinsing liquid can be applied being directed onto the wafer by means of at least one nozzle of a nozzle arrangement, said nozzle being designed as a fan nozzle or a full-cone nozzle or a hollow-cone nozzle, the inlet being able to be designed as the nozzle. As a result of the application of the rinsing liquid to the wafer, the wafer can be rinsed. This allows the wafer to be cleaned further. After filling the basin, a sample of the rinsing liquid can be taken from the basin, the sample being able to be analyzed by means of a sample-analysis device of the rinsing station. Based on an analysis result, in particular based on the purity of the rinsing liquid determined by means of the sample-analysis device, it can be concluded whether the wafer has been cleaned or not. The steps of emptying the basin of contaminated rinsing liquid, filling the basin with fresh rinsing liquid and taking and analyzing a sample of the rinsing liquid can be repeated as often as required until the wafer is cleaned. If the analysis shows that the wafer is clean, the basin can be emptied, when the wafer is disposed in the processing chamber. Subsequently, the wafer can then be removed from the processing chamber. Alternatively, the basin can also be emptied after the wafer has been removed from the processing chamber. The basin can then be filled with rinsing liquid. The rinsing station is then available for rinsing another wafer.

The wafer can also be inserted in the empty basin or partially filled basin, the basin being able to be filled afterwards. A sample can then be taken and analyzed.

A “filled basin” refers to a state of the basin in which the basin is filled to a target level, in particular a level at which the rinsing liquid in the basin is at the level of an overflow of the basin.

For the advantageous effects of the method, reference is made to the description of the advantages of the rinsing station according to the invention.

The device according to the invention for producing contact metallizations on terminal faces of wafers comprises at least one rinsing station according to the invention, a processing chamber of the rinsing station being configured to receive a transport receptacle having a plurality of wafers received therein, the device having a manipulator for handling the transport receptacle.

Advantageously, the device can comprise a plurality of workstations which are preferably disposed in a line, each workstation having a processing chamber for receiving the transport receptacle having the wafers received therein, the plurality of workstations comprising the rinsing station as a workstation, the device having a conveyor on which the manipulator is disposed, the manipulator, in interaction with the conveyor, allowing the transport receptacle to be disposed in a selectable order of the processing chambers in a conveying direction.

Advantageously, the manipulator can have a horizontally movable carrier which is connected to a conveyor belt of the conveyor and which has at least one gripping arm which is vertically moveable with respect to the carrier.

Advantageously, the device can comprise an entry/exit station for equipping the device with at least one transport receptacle and/or the plurality of workstations can comprise at least one depositing station, at least one cleaning station and/or at least one drying station. The depositing station can be intended for depositing a metal, in particular galvanically or electrolessly, in particular nickel, zinc, palladium, gold or the like, on the terminal faces. The metal can be dissolved in a liquid, such as nitric acid. A solution of the metal dissolved in the liquid can be received in a processing chamber of the depositing station. The cleaning station can be intended for cleaning the wafers, in particular the terminal faces, using a cleaning liquid, for example nitric acid. The cleaning liquid can be received in a processing chamber of the cleaning station. The drying station can be intended for drying the wafers, in particular wafer surfaces.

### BRIEF DESCRIPTION OF THE DRAWING FIGURES

In the following, a preferred embodiment of the invention is explained in more detail with reference to the accompanying drawings.

FIG. 1 shows a perspective view of a rinsing station from one side, diagonally from the top right.

FIG. 2 shows a perspective view of the rinsing station from the side, diagonally from the top left.

FIG. 3 shows a top view of the rinsing station.

FIG. 4 shows a sectional view of the rinsing station.

FIG. 5 shows another sectional view of the rinsing station

FIG. 6 shows a partial perspective view of the rinsing station in an area of a sample-analysis device of the rinsing station.

FIG. 7 shows a perspective view of the sample-analysis device partially exploded.

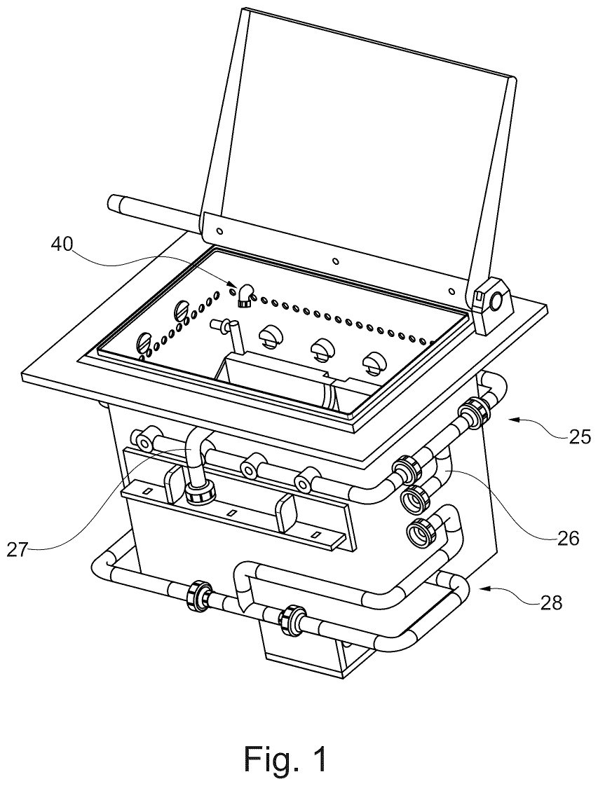

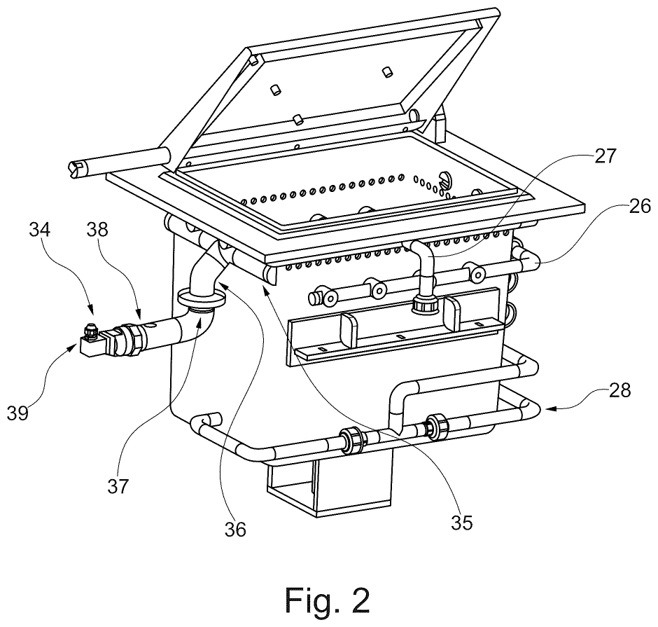

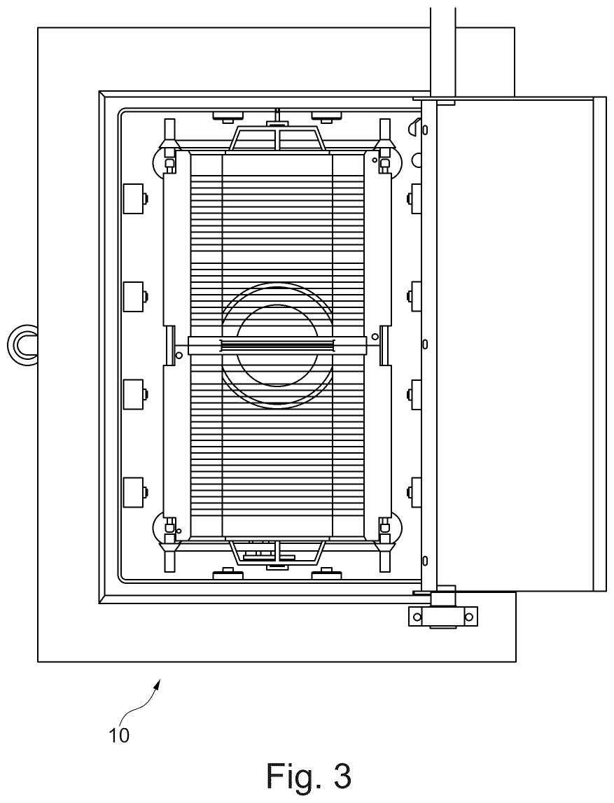

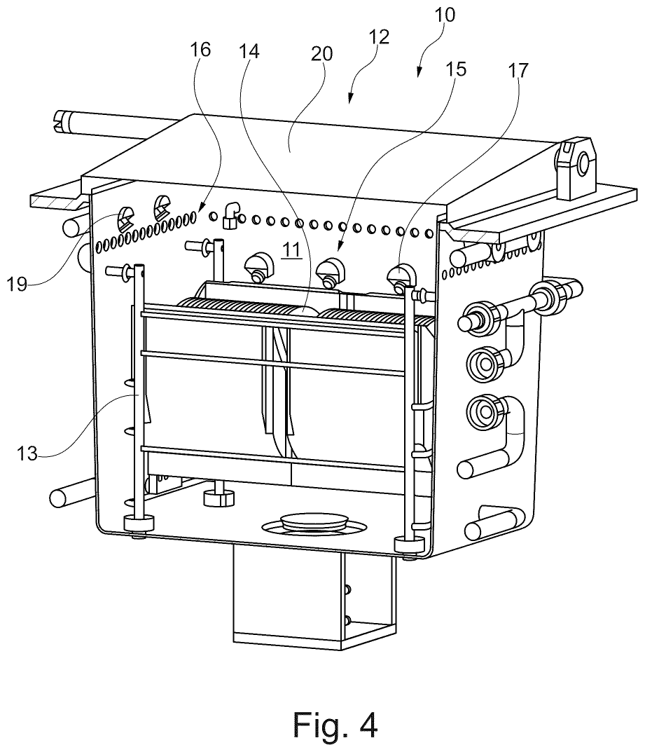

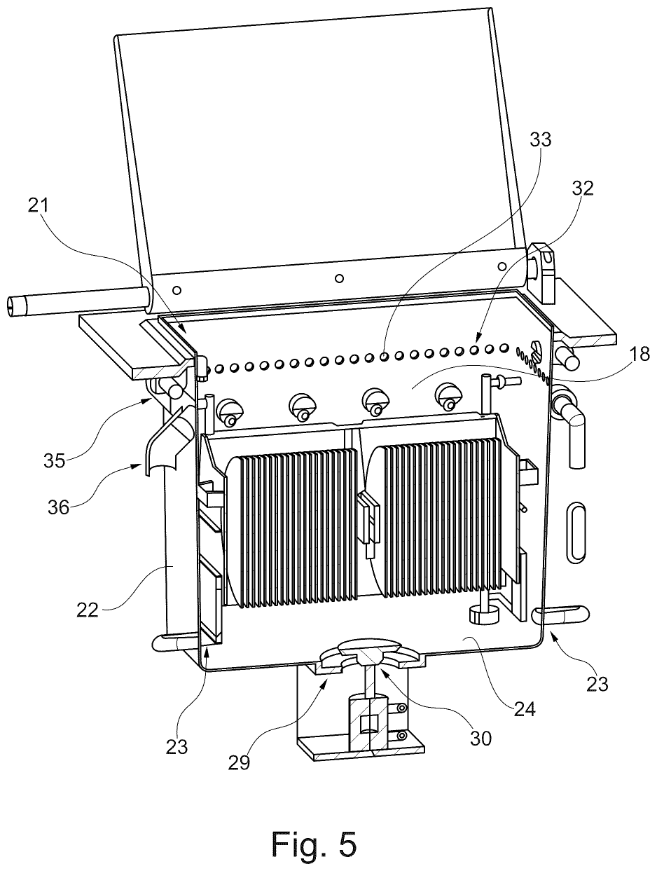

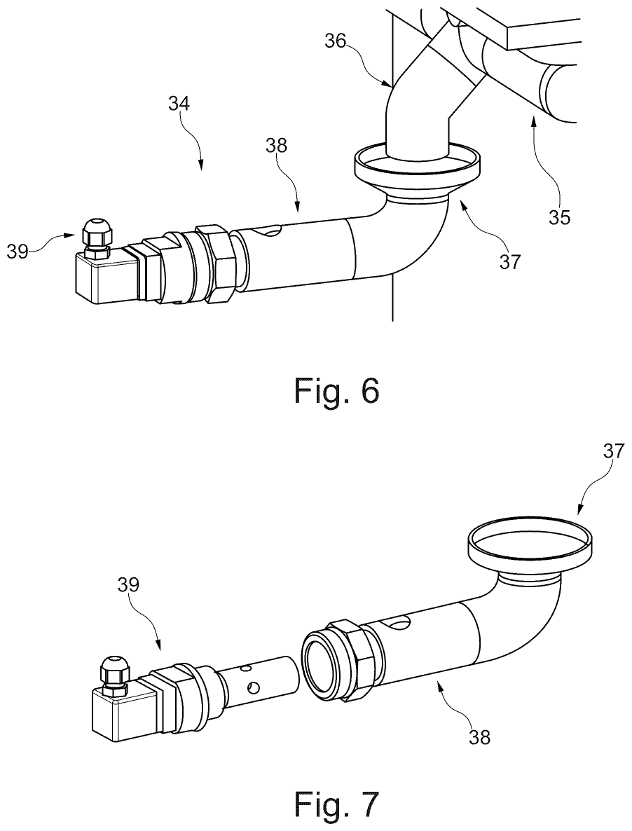

A combined view of FIGS. 1 to 7 shows a rinsing station 10, comprising a basin 12 forming a processing chamber 11 and serving to receive a rinsing liquid (not shown), in particular containing deionized water, for rinsing a plurality of wafers 14 received in a transport receptacle 13 which can be received in the processing chamber 11, the plurality of wafers 14 being able to inserted in the basin 12 from above in order to carry out a rinsing process and/or being able to be removed from the basin 12 and thus being able to be handled by means of a manipulator (not shown) of a device (not shown) for producing contact metallizations, the rinsing station 10 being able to form a component of said device.

The basin 12 has an inlet 15 for feeding the rinsing liquid into the basin 12, the inlet 15 being designed as a nozzle arrangement 16. The nozzle arrangement 16 has a plurality of nozzles 17 designed as fan nozzles and/or flat-jet nozzles, by means of which the rinsing liquid can be applied being directed onto the wafers 14. In this context, the nozzles 17 are disposed in a row at equal distances from each other on two opposing longitudinal walls 18 of the basin 12. In the present case, on each longitudinal wall 18, four nozzles 17 are provided. The basin 12 has at least one valve (not shown here) which is assigned to the nozzles 17. Furthermore, the nozzle arrangement 16 has a plurality of other nozzles 19 which are also designed as fan nozzles and/or flat-jet nozzles, by means of which the rinsing liquid can be applied being directed onto a pivotable lid 20 of the basin 12, which covers an opening 21 of the basin 12 in a closed position of the lid 20. The other nozzles 19 are disposed in a row at equal distances from each other on two opposing transverse walls 22 of the basin 12. In the present case, on each transverse wall 22, two further nozzles 19 are provided. The basin 12 has at least one other valve (not shown here) assigned to the other nozzles 19. The longitudinal walls 18 are longer than the transverse walls 22. However, it is also conceivable that the longitudinal walls 18 and the transverse walls 22 have the same length. The longitudinal walls 18 and the transverse walls 22 form lateral walls 18, 22 of the basin 12.

Furthermore, the basin 12 has another inlet 23 for feeding the rinsing liquid into the basin 12, which is formed by two openings (not shown here), each of which is provided in an area of an edge of the respective transverse wall 22, said edge being adjacent to a bottom wall 24 of the basin 12.

Furthermore, the rinsing station 10 comprises a pipe arrangement 25 connected to the inlet 15, the pipe arrangement 25 comprising a first distribution piping 26 connected to the nozzles 17 and a second distribution piping 27 formed separately from the first distribution piping 26 and connected to the other nozzles 19. In addition, the rinsing station 10 comprises another pipe arrangement 28 which is connected to the other inlet and is designed as a distribution piping.

Furthermore, the basin 12 has an outlet 29, which is disposed centrally on the bottom wall 24, is designed as a free drain, and serves to drain the rinsing liquid from the basin 12. The basin 12 has a valve 30 assigned to the outlet 29.

Furthermore, the basin 12 has an overflow 31, the longitudinal walls 18 and the transverse walls 22 each having a perforation 32 which is formed in an area of an edge of the respective longitudinal wall, said edge being adjacent to the opening 21, and/or in an area of an edge of the respective transverse wall, said edge being adjacent to the opening 21, and which forms the overflow 31. The perforation 32 has a row of holes 33 extending parallel to the respective edge 33 for each longitudinal wall 18 and/or transverse wall 22. The nozzles 17 are disposed on the longitudinal walls 18 below the holes 33, while the other nozzles 19 are disposed above the holes 33 on the transverse walls 22

Furthermore, the rinsing station 10 comprises a sample-analysis device 34, which is configured to analyze a sample of the rinsing liquid taken from the basin 12. In this context, the sample-analysis device 34 is connected to the overflow 31 in such a manner that the sample can be taken from the rinsing liquid drained from the basin 12 via the overflow 31. For this purpose, on the outside of the basin 12, a deflection channel 35 of the basin 12 is provided, via which the rinsing liquid drained from the basin 12 via the overflow 31 can be supplied to the sample analysis device 34. The deflection channel 35 has an exit 36 which opens into an overflow vessel 37 of the sample-analysis device 34, from where the rinsing liquid and/or the sample can reach a sample sensor 39 of the sample-analysis device 34 for a measuring probe (not shown here) of the sample-analysis device 34 via a measuring path 38 of the sample-analysis device sample 34 which serves for calming and preventing it from running dry. The measuring path 38 is formed in one piece with the overflow vessel 37.

Furthermore, the rinsing station 10 comprises a control device (not shown here), which is configured to control feeding the rinsing liquid into the basin 12 via the inlet 15 and the other inlet 23 and to drain the rinsing liquid from the basin 12 via the outlet 29. In this context the control device controls the nozzles 17, the other nozzles 19 and the outlet 29, of which only the valve 30 is shown here.

Furthermore, the rinsing station 10 comprises a filling-level measuring device 40 (only partially shown), which is configured to measure a filling level in the basin 12.

Furthermore, the rinsing station 10 comprises a temperature-control device (not shown here) for controlling the temperature of the rinsing liquid before the rinsing liquid is fed into the basin 12.

In the present instance, the nozzles 17 and the other nozzles 19 are designed as fan nozzles and/or flat-jet nozzles. Instead of fan nozzles and/or flat-jet nozzles, full-cone nozzles or hollow-cone nozzles can also be provided. The nozzles 17 and/or the other nozzles 19 can also be a combination of fan nozzles and/or flat-jet nozzles and/or full-cone nozzles and/or hollow-cone nozzles.

### LIST OF REFERENCE NUMERALS

10 rinsing station
11 processing chamber
12 basin
13 transport receptacle
14 wafer
15 inlet
16 nozzle arrangement
17 nozzle
18 longitudinal wall
19 nozzle
20 lid
21 opening
22 transverse wall
23 inlet
24 bottom wall
25 pipe arrangement
26 distribution piping
27 distribution piping
28 pipe arrangement
29 outlet
30 valve
31 overflow
32 perforation
33 hole
34 sample-analysis device
35 deflection channel
36 exit
37 overflow vessel
38 measuring path
39 sample sensor
40 filling-level measuring device

1. A rinsing station (10), comprising a basin (12) forming a processing chamber (11) and serving to receive a rinsing liquid, in particular containing deionized water, for rinsing a wafer (14) receivable in the processing chamber, the basin having at least one inlet (15) for feeding the rinsing liquid into the basin,
wherein the inlet is designed as a nozzle arrangement (16), the nozzle arrangement having at least one nozzle (17) by means of which the rinsing liquid can be applied being directed onto the wafer, the nozzle being designed as a fan nozzle or a full-cone nozzle or a hollow-cone nozzle.

2. The rinsing station according to claim 1,
wherein the basin (12) has an outlet (29) serving to drain the rinsing liquid from the basin.

3. The rinsing station according to claim 1, wherein
the rinsing station (10) comprises a sample-analysis device (34), which is configured to analyze a sample of the rinsing liquid taken from the basin (12).

4. The rinsing station according to claim 3,
wherein the basin (12) has an overflow (31), the sample-analysis device (34) being connected to the overflow in such a manner that the sample is taken from the rinsing liquid drained from the basin via the overflow.

5. The rinsing station according to claim 4,
wherein lateral walls (18, 22) of the basin (12) each have a perforation (32) which is formed in an area of an edge of the lateral walls and forms the overflow (31).

6. The rinsing station according to claim 1,
wherein the basin (12) is configured such that a transport receptacle (13) having a plurality of wafers (14) received therein is inserted into the basin from above.

7. The rinsing station according to claim 1,
wherein the basin (12) has another inlet (23) for feeding the rinsing liquid into the basin.

8. The rinsing station according to claim 1,
wherein the rinsing station (10) comprises at least one pipe arrangement (25) connected to the inlet (15).

9. The rinsing station according to claim 1 wherein the rinsing station (10) comprises a control device, which is configured to at least control feeding the rinsing liquid into the basin (12) via the inlet (15).

10. The rinsing station according to claim 1 wherein the rinsing station (10) comprises a filling-level measuring device (40), which is configured to measure a filling level in the basin (12).

11. The rinsing station according to claim 1 the basin (12) has a lid (20), which covers an opening (21) of the basin in a closed position of the lid.

12. The rinsing station according to claim 11,
wherein the nozzle arrangement (16) has at least one other nozzle (19) by means of which the rinsing liquid can be applied being directed onto the lid (20), the other nozzle being designed as a fan nozzle or a full-cone nozzle or a hollow-cone nozzle.

13. The rinsing station according to claim 1, wherein the rinsing station (10) comprises a temperature-control device for controlling the temperature of the rinsing liquid.

14. A device for producing contact metallizations on terminal faces of wafers, the device comprising at least one rinsing station (10) according to claim 1, a processing chamber (11) of the rinsing station being configured to receive a transport receptacle (13) having a plurality of wafers (14) received therein, the device having a manipulator for handling the transport receptacle.

15. The device according to claim 14, wherein
the device comprises a plurality of workstations, each workstation having a processing chamber for receiving the transport receptacle (13) having the wafers (14) received therein, the plurality of workstations comprising the rinsing station (10) as a workstation, the device having a conveyor on which the manipulator is disposed, the manipulator, in interaction with the conveyor, allowing the transport receptacle to be disposed in a selectable order of the processing chambers in a conveying direction.

16. The device according to claim 15,
wherein the manipulator has a horizontally moveable carrier which is connected to a conveyor belt of the conveyor and which has at least one gripping arm which is vertically moveable with respect to the carrier.

17. The device according to claim 15, wherein the device comprises an entry/exit station for equipping the device with at least one transport receptacle and/or the plurality of workstations comprises at least one depositing station and/or at least one cleaning station and/or at least one drying station.
